(19) United States
(12) Patent Application Publication
(10) Pub. No.: US 2023/0257869 A1
(43) Pub. Date: Aug. 17, 2023

(54) SYSTEM FOR DEPOSITING PIEZOELECTRIC MATERIALS, METHODS FOR USING THE SAME, AND MATERIALS DEPOSITED WITH THE SAME

(71) Applicant: QORVO BIOTECHNOLOGIES, LLC, Plymouth, MN (US)

(72) Inventors: Derya Deniz, McKinney, TX (US); Philip Johnston, Hudson Oaks, TX (US); Jay Helland, Crandall, TX (US); John Belsick, Bend, OR (US); Kevin McCarron, Bend, OR (US)

(21) Appl. No.: 18/013,124

(22) PCT Filed: Oct. 22, 2020
(86) PCT No.: PCT/US2020/056792

§ 371 Date: Dec. 27, 2022

Related U.S. Application Data
(60) Provisional application No. 63/045,943, filed on Jun. 30, 2020.

(51) Int. Cl. C23C 14/56; H03H 3/02; H03H 9/17; H01J 37/34; H01J 37/32; C23C 14/54; C23C 14/50; C23C 14/35; C23C 14/02; C23C 14/22; C30B 23/00; C30B 23/06

(52) U.S. Cl. CPC C23C 14/566; H03H 3/02; H03H 9/173; H03H 9/175; H01J 37/3447; H01J 37/32899; H01J 37/32743; H01J 37/32458; H01J 37/3417; H01J 37/3405; C23C 14/568; C23C 14/541; C23C 14/50; C23C 14/35; C23C 14/02; C23C 14/225; C30B 23/005; C30B 23/063; H03H 2003/021; H03H 2003/025; H01J 2237/20285; H01J 2237/332; H01J 2237/2001; H01J 2237/2002; H01J 2237/20235; H01J 2237/20214; H01J 2237/201; H01J 2237/2007; H01J 2237/0455

(57) ABSTRACT

A deposition system is disclosed that allows for growth of inclined c-axis piezoelectric material structures. The system integrates various sputtering modules to yield high quality films and is designed to optimize throughput lending it to a high-volume in manufacturing environment. The system includes two or more process modules including an off-axis module constructed to deposit material at an inclined c-axis and a longitudinal module constructed to deposit material at normal incidence; a central wafer transfer unit including a load lock, a vacuum chamber, and a robot disposed within the vacuum chamber and constructed to transfer a wafer substrate between the central wafer transfer unit and the two or more process modules; and a control unit operatively connected to the robot.

### CROSS REFERENCE TO RELATED APPLICATIONS

This application claims the benefit of U.S. Provisional Patent Application No. 63/045,943, filed 30 Jun. 2020, the disclosure of which is incorporated by reference herein in its entirety.

### FIELD

The present disclosure relates to systems for depositing piezoelectric materials. In particular, the present disclosure relates to systems for depositing piezoelectric materials with inclined c-axis and normal incidence piezoelectric materials. The present disclosure further relates to methods for using such systems, and to materials deposited with such systems.

### BACKGROUND

Hexagonal crystal structure piezoelectric materials such as AlN and ZnO are of commercial interest due to their piezoelectric and electroacoustic properties. A primary use of electroacoustic technology has been in the telecommunication field (e.g., for oscillators, filters, delay lines, etc.). More recently, there has been a growing interest in using electroacoustic devices in high frequency sensing applications due to the potential for high sensitivity, resolution, and reliability. However, it is not trivial to apply electroacoustic technology in certain sensor applications—particularly sensors operating in liquid or viscous media (e.g., chemical and biochemical sensors)—since longitudinal and surface waves exhibit considerable acoustic leakage into such media, thereby resulting in reduced resolution.

In the case of a piezoelectric crystal resonator, an acoustic wave may embody either a bulk acoustic wave (BAW) propagating through the interior (or ‘bulk’) of a piezoelectric material, or a surface acoustic wave (SAW) propagating on the surface of the piezoelectric material. SAW devices involve transduction of acoustic waves (commonly including two-dimensional Rayleigh waves) utilizing interdigital transducers along the surface of a piezoelectric material, with the waves being confined to a penetration depth of about one wavelength. BAW devices typically involve transduction of an acoustic wave using electrodes arranged on opposing top and bottom surfaces of a piezoelectric material. In a BAW device, different vibration modes can propagate in the bulk material, including a longitudinal mode and two differently polarized shear modes, wherein the longitudinal and shear bulk modes propagate at different velocities. The longitudinal mode is characterized by compression and elongation in the direction of the propagation, whereas the shear modes consist of motion perpendicular to the direction of propagation with no local change of volume. The propagation characteristics of these bulk modes depend on the material properties and propagation direction respective to the crystal axis orientations. Because shear waves exhibit a very low penetration depth into a liquid, a device with pure or predominant shear modes can operate in liquids without significant radiation losses (in contrast with longitudinal waves, which can be radiated in liquid and exhibit significant propagation losses). Restated, shear mode vibrations are beneficial for operation of acoustic wave devices with fluids because shear waves do not impart significant energy into fluids.

Certain piezoelectric thin films are capable of exciting both longitudinal and shear mode resonance. To excite a wave including a shear mode using a standard sandwiched electrode configuration device, a polarization axis in a piezoelectric thin film must generally be non-perpendicular to (e.g., tilted relative to) the film plane. Hexagonal crystal structure piezoelectric materials such as (but not limited to) aluminum nitride (AlN) and zinc oxide (ZnO) tend to develop their polarization axis (i.e., c-axis) perpendicular to the film plane, since the (0001) plane typically has the lowest surface density and is thermodynamically preferred. Certain high-temperature processes may be used to grow tilted c-axis films, but providing full compatibility with microelectronic structures such as metal electrodes or traces requires a low temperature deposition process (e.g., typically below about 300° C.).

Low temperature deposition methods such as reactive radio frequency magnetron sputtering have been used for preparing tilted AlN films. However, these processes tend to result in deposition angles that vary significantly with position over the area of a substrate, which leads to a c-axis direction of the deposited piezoelectric material that varies with radial position of the target to the source.

One effect of the lack of uniformity of c-axis tilt angle of the AlN film structure over the substrate is that if the AlN film-covered substrate were to be diced into individual chips, the individual chips would exhibit significant variation in c-axis tilt angle and concomitant variation in acoustic wave propagation characteristics. Such variation in c-axis tilt angle would render it difficult to efficiently produce large numbers of resonator chips with consistent and repeatable performance.

Improved methods and systems for producing bulk films with c-axis tilt have been described, where the c-axis tilt of the bulk layer is primarily controlled by controlling the deposition angle. For example, a device and method for depositing seed and bulk layers with a tilted c-axis are described in U.S. Pat. No. 9,922,809 entitled “Deposition System for Growth of Inclined C-Axis Piezoelectric Material Structures;” U.S. Pat. No. 10,541,662 entitled “Methods for Fabricating Acoustic Structure with Inclined C-Axis Piezoelectric Bulk and Crystalline Seed Layers;” U.S. Pat. No. 10,574,204 entitled “Acoustic Resonator Structure with Inclined C-Axis Piezoelectric Bulk and Crystalline Seed Layers;” U.S. Pat. No. 10,541,663 entitled “Multi-Stage Deposition System for Growth of Inclined C-Axis Piezoelectric Material Structures;” and U.S. Pat. No. 10,063,210 entitled “Methods for Producing Piezoelectric Bulk and Crystalline Seed Layers of Different C-Axis Orientation Distributions.”

Further improvements to deposition systems are desired.

### BRIEF DESCRIPTION OF DRAWINGS

FIG. 1 is a schematic overview of a deposition system according to an embodiment.

FIGS. 2A-2D are schematic depictions of a robot of the deposition system of FIG. 1 retrieving and transferring a wafer substrate according to an embodiment.

FIGS. 3A-3D are schematic cross-sectional side views of the robot delivering a wafer to an off-axis module of the deposition system of FIG. 2D according to an embodiment.

FIGS. 4A-4B are schematic cross-sectional front views of the robot delivering a wafer to an off-axis module of the deposition system of FIG. 2D according to an embodiment.

FIG. 5 is a downwardly-facing cross-sectional view of a portion of a linear sputtering apparatus of the off-axis module of the deposition system of FIG. 1 according to an embodiment.

FIG. 6 is a schematic cross-sectional view of a pre-sputter/degas module of the deposition system of FIG. 2D according to an embodiment.

FIG. 7 is a schematic cross-sectional view of a longitudinal module of the deposition system of FIG. 2D according to an embodiment.

FIGS. 8A-8D are schematic views illustrating a process for depositing an inclined c-axis seed layer and a bulk layer on a substrate to achieve a desired c-axis tilt in accordance with an embodiment described herein.

FIG. 9 is a schematic cross-sectional view of a portion of a bulk acoustic wave solidly mounted resonator device including an inclined c-axis hexagonal crystal structure piezoelectric material bulk layer as disclosed herein, with the resonator device including an active region with a portion of the piezoelectric material arranged between overlapping portions of a top side electrode and a bottom side electrode.

FIG. 10 is a schematic cross-sectional view of a film bulk acoustic wave resonator (FBAR) device according to one embodiment including an inclined c-axis hexagonal crystal structure piezoelectric material bulk layer arranged over a crystalline seed layer as disclosed herein, with the FBAR device including a substrate defining a cavity covered by a support layer, and including an active region registered with the cavity with a portion of the piezoelectric material arranged between overlapping portions of a top side electrode and a bottom side electrode.

### SUMMARY

A system and method for depositing piezoelectric materials onto wafer substrates are described. The system and method may be used to deposit piezoelectric materials including layers of inclined c-axis and normal incidence piezoelectric material. The system of the present disclosure is suitable for a continuous process and is capable of performing two or more steps of the process in a single system.

The system for depositing material onto a substrate includes two or more process modules including an off-axis module constructed to deposit material at an inclined c-axis, and a longitudinal module constructed to deposit material at normal incidence; and a central wafer transfer unit including a load lock, a vacuum chamber, and a robot disposed within the vacuum chamber and constructed to transfer a wafer substrate between the central wafer transfer unit and the two or more process modules; and a control unit operatively connected to the robot. The central housing unit may include a cooling station constructed to control wafer temperature. The two or more process modules may include a pre-sputter module constructed to prepare wafer substrates for deposition of material. The system may include a cassette elevator for housing a plurality of wafer substrates accessible by the robot. The robot may be constructed to retrieve a wafer substrate from the cassette elevator and to transfer the retrieved wafer substrate to one of the process modules.

The off-axis module may include a linear sputtering apparatus including a target surface configured to eject metal atoms; a wafer chuck including a support surface and configured to receive and secure in place a wafer substrate; and a collimator including a plurality of guide members defining a plurality of collimator apertures arranged between the linear sputtering apparatus and the wafer chuck, the collimator being linearly translatable in a direction substantially parallel to the target surface, wherein the target surface is arranged non-parallel to the support surface. The system may further include a second off-axis module.

The longitudinal module may include a circular sputtering apparatus including a target surface configured to eject metal atoms; and a wafer chuck including a support surface and configured to receive and secure in place a wafer substrate, wherein the target surface is arranged parallel to the support surface.

A method of depositing material onto a substrate may include transferring a wafer substrate from a load lock to a central wafer transfer unit; transferring the wafer substrate from the central wafer transfer unit to an off-axis module and depositing material onto the wafer substrate at an inclined c-axis; and transferring the wafer substrate from the central wafer transfer unit to a longitudinal module and depositing material onto the wafer substrate at normal incidence. Transferring of the wafer substrate may be done by a robot arm. The method may include transferring the wafer substrate into a pre-sputter module and cleaning the wafer substrate by plasma sputter. The depositing of material onto the wafer substrate at an inclined c-axis may include depositing a seed layer. The depositing of material onto the wafer substrate at normal incidence may include depositing a bulk layer. While material is deposited onto the wafer substrate, a second wafer substrate may be transferred from the central wafer transfer unit to a second off-axis module for depositing material onto the second wafer substrate at an inclined c-axis.

### DETAILED DESCRIPTION

The present disclosure relates to systems for depositing piezoelectric materials. In particular, the present disclosure relates to systems for depositing piezoelectric materials including inclined c-axis and normal incidence piezoelectric materials. The systems of the present disclosure are suitable for a continuous process and is capable of performing two or more steps of the process in a single system.

A deposition system is disclosed that allows for growth of inclined c-axis piezoelectric material structures. This system integrates various sputtering modules to yield high quality films and is designed to optimize throughput lending it to a high-volume manufacturing environment. This unique combination of sputter technologies is not found in a commercially available thin film deposition system. By integrating the various modules involved in the production of the piezoelectric material structures, removing the work piece from one module to the external environment and moving it to another, thus exposing the work piece to potential contamination, can be avoided. Using the system of the present disclosure may save time and energy and allows streamlining of the process. Use of the system also helps avoid air breaks, exposure to moisture, and potential contamination of the work piece during the process, thus leading to a higher quality end product.

The term “c-axis” is used here to refer to the (002) direction of a deposited crystal with a hexagonal wurtzite structure. The c-axis is typically the longitudinal axis of the crystal.

The terms “c-axis tilt,” “c-axis orientation,” and “c-axis incline” are used here interchangeably to refer to the angle of the c-axis relative to a normal of the surface plane of the deposition substrate.

When referring to c-axis tilt or c-axis orientation, it should be understood that even if a single angular value is given, the crystals in a deposited crystal layer (e.g., a seed layer or a bulk layer) may exhibit a distribution of angles. The distribution of angles typically approximately follows a normal (e.g., Gaussian) distribution that can be graphically demonstrated, for example, as a two-dimensional plot resembling a bell-curve, or by a pole figure.

The term “incidence angle” is used here to refer to the angle at which atoms are deposited onto a substrate, measured as the angle between the deposition pathway and a normal of the surface plane of the substrate.

The term “substrate” is used here to refer to a material onto which a seed layer or a bulk layer may be deposited. The substrate may be, for example, a wafer, or may be a part of a resonator device complex or wafer, which may also include other components, such as an electrode structure arranged over at least a portion of the substrate. A seed layer is not considered to be “a substrate” in the embodiments of this disclosure.

When referring to deposition of crystals “on a substrate,” there may be intervening layers (e.g., a seed layer) between the substrate and the crystals. However, the expressions “directly on a substrate” or “on the surface of the substrate” are intended to exclude any intervening layers.

The term “seed layer” is used here to refer to a first layer deposited onto a substrate, and onto which a bulk material layer may be deposited.

The term “bulk layer” is used here to refer to a crystalline layer that exhibits primarily (002) texture. The bulk layer may be formed in one or more steps. Reference to the bulk layer in this disclosure refers to the entire bulk layer, whether the bulk layer is formed in a single step, two steps, or more than two steps.

The term “vacuum” is used here to refer to a subatmospheric pressure condition, where atmospheric pressure is 760 Torr.

The term “substantially” as used here has the same meaning as “nearly completely,” and can be understood to modify the term that follows by at least about 90%, at least about 95%, or at least about 98%.

The terms “parallel” and “substantially parallel” with regard to the crystals refer to the directionality of the crystals. Crystals that are substantially parallel not only have the same or similar c-axis tilt but also point in the same or similar direction.

The term “about” is used here in conjunction with numeric values to include normal variations in measurements as expected by persons skilled in the art, and is understood have the same meaning as “approximately” and to cover a typical margin of error, such as ±5% of the stated value.

All scientific and technical terms used herein have meanings commonly used in the art unless otherwise specified. The definitions provided herein are to facilitate understanding of certain terms used frequently herein and are not meant to limit the scope of the present disclosure.

As used here, the singular forms “a”, “an”, and “the” encompass embodiments having plural referents, unless the content clearly dictates otherwise.

As used here, the term “or” is generally employed in its sense including “and/or” unless the content clearly dictates otherwise. The term “and/or” means one or all of the listed elements or a combination of any two or more of the listed elements.

As used here, “have”, “having”, “include”, “including”, “comprise”, “comprising” or the like are used in their open-ended sense, and generally mean “including, but not limited to.” It will be understood that “consisting essentially of,” “consisting of,” and the like are subsumed in “comprising” and the like. As used herein, “consisting essentially of,” as it relates to a composition, product, method or the like, means that the components of the composition, product, method or the like are limited to the enumerated components and any other components that do not materially affect the basic and novel characteristic(s) of the composition, product, method or the like.

The words “preferred” and “preferably” refer to embodiments of the invention that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure, including the claims.

The recitations of numerical ranges by endpoints include all numbers subsumed within that range (e.g., 1 to 5 includes 1, 1.5, 2, 2.75, 3, 3.80, 4, 5, etc. or 10 or less includes 10, 9.4, 7.6, 5, 4.3, 2.9, 1.62, 0.3, etc.). Where a range of values is “up to” a particular value, that value is included within the range.

Any direction referred to here, such as “top,” “bottom,” “left,” “right,” “upper,” “lower,” and other directions and orientations are described herein for clarity in reference to the figures and are not to be limiting of an actual device or system or use of the device or system. Devices or systems as described herein may be used in a number of directions and orientations.

Specialized deposition equipment may be used to deposit inclined c-axis piezoelectric material structures to control the c-axis orientation relative to the normal of the substrate/electrode. Such deposition is enabled by understanding the mechanism of film growth and the ability to set the film crystallographic structure. Work carried out has developed novel deposition techniques integrated with stand-alone deposition systems to accomplish this task.

Issues with existing deposition systems include that multiple process models are not integrated onto a single platform. For commercial device fabrication utilizing wafer level processes, throughput is also a consideration. There is a need for a system that includes specialized process modules and integrates the entire work cell. This type of system has an advantage over utilizing separate systems to deposit the piezoelectric film structure. Preferably, the system is capable of processing wafers of any desired size, such as up to 200 mm or even greater. In some cases, the system is configured to be able to process wafers of up to 200 mm in size.

According to an embodiment, the system includes a centralized vacuum platform that includes a vacuum chamber and a robot housed in the vacuum chamber; an off-axis module for depositing material at an inclined c-axis; a longitudinal module for depositing material at normal incidence; and system control architecture. According to some embodiments, the system comprises the following process elements:

A centralized vacuum platform for manipulation of wafers between process modules;

A cooling station module to control wafer temperature between individual process sequences;

A pre-sputter/degas module for preparation of the wafer substrate prior to deposition processes;

Off-axis module(s) for inclined c-axis film deposition;

A longitudinal module for normal incidence film deposition; and

System control architecture.

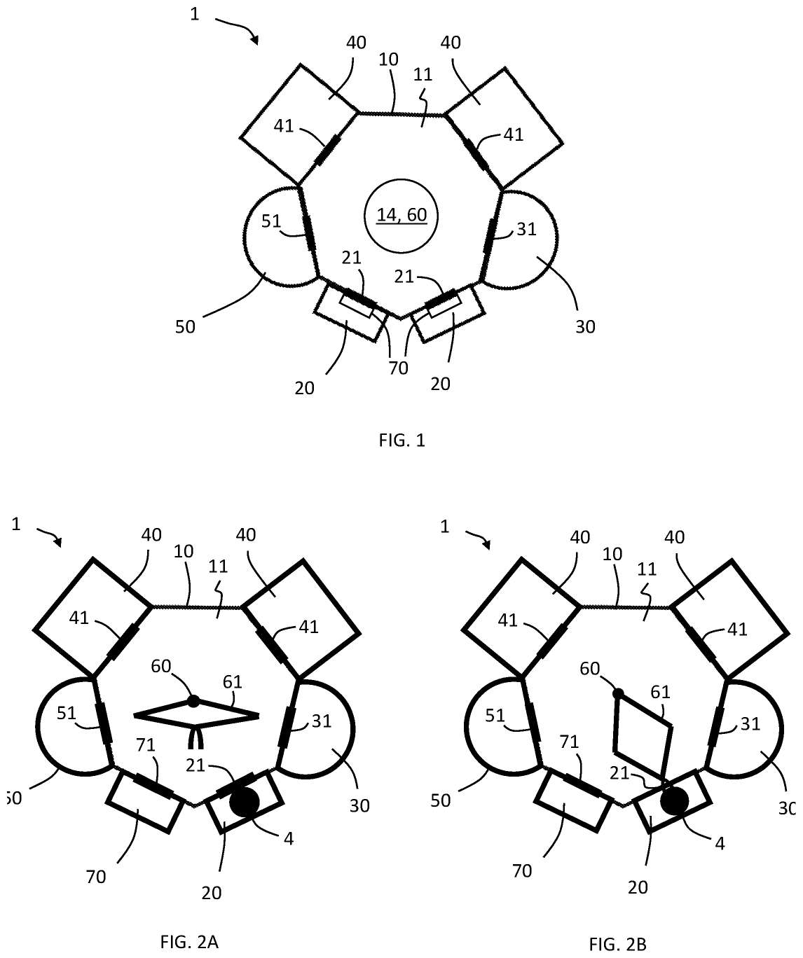

A schematic view of the system 1 is shown in FIG. 1, showing a centralized vacuum platform defined by a central wafer transfer unit 10 with a vacuum chamber 11, which houses a wafer transfer robot 60. The system control architecture is embodied in the system control unit 14. The system 1 includes a wafer storage unit, such as a wafer cassette elevator 20, that is constructed to house a plurality of wafers. The system 1 further includes a pre-sputter/degas module 30, one or more off-axis modules 40, a longitudinal module 50, and a cooling station module 70. The various modules may be separated from the central wafer transfer unit 10 by doors or valves, such as gate valves or access ports 21, 31, 41, 51.

The system of the present disclosure may be used for producing bulk films with a c-axis tilt. For example, the system of the present disclosure may be used to produce structures including inclined c-axis hexagonal crystal structure piezoelectric materials. Such piezoelectric materials may include aluminum nitride (AlN) and zinc oxide (ZnO). The inclined c-axis hexagonal crystal structure piezoelectric materials may be used, for example, in various resonators as well as in thin film electroacoustic and/or sensor devices. Films made with inclined c-axis hexagonal crystal structure piezoelectric materials may be particularly useful in sensors operating in liquid/viscous media, such as chemical and biochemical sensors.

According to an embodiment, the various modules are configured with specific functionality to obtain desired film properties in resultant device structures, and to optimize throughput as stated below.

According to an embodiment, the centralized vacuum platform comprises a central wafer transfer unit that includes a vacuum chamber and a wafer transfer robot disposed within the vacuum chamber for transferring wafer substrates. The central wafer transfer unit may include or be connected to one or more wafer cassette elevators for housing a plurality of wafers. The wafer substrates inside the wafer cassette elevator are retrievable by the robot. The centralized vacuum platform may further include one or more (e.g., two) load locks and a plurality of access ports between the centralized vacuum platform and the various modules of the system. The robot may be constructed to retrieve a wafer substrate from the cassette and to transfer the retrieved wafer substrate to one of the process modules. Having multiple load locks may help process wafers through the system in a continuous manner. The central wafer transfer unit may be positioned centrally between the process modules.

According to an embodiment, the centralized vacuum platform includes:
a. One or more (e.g., two) load locks for manipulation of wafers within the tool in a continuous manner.
b. Access ports between the centralized vacuum platform and each of the modules.

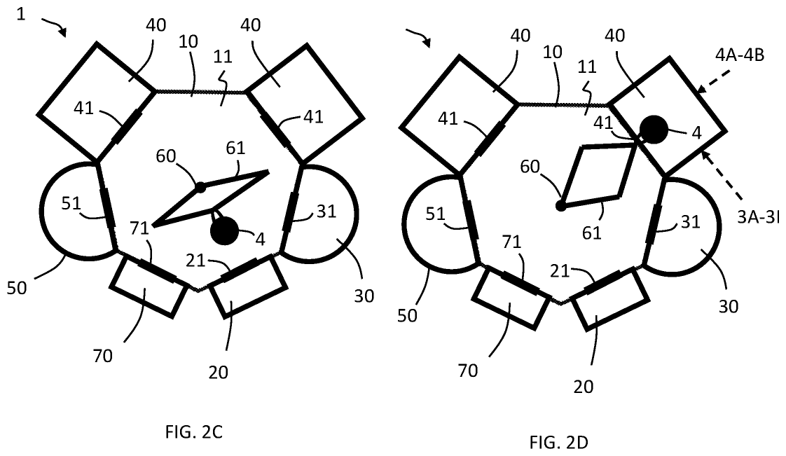

As shown schematically in FIGS. 2A-2D, the robot 60 may have one or more robot arms 61, which may be configured to retrieve and transfer wafers 4 between the various modules. In FIG. 2A, the robot arm 61 is in a home position inside the central wafer transfer unit 10. The robot arm 61 may be extended into an extended position, as shown in FIG. 2B, to retrieve a wafer 4 from one of the modules, such as the wafer cassette elevator 20. The robot arm 61 may again retract, as shown in FIG. 2C, and then rotate and extend to deliver the wafer 4 to another module, such as the off-axis module 40, as shown in FIG. 2D. The robot arm 61 may access the modules through the gate valve or access port 21, 31, 41, 51.

According to an embodiment, the system 1 includes a cooling station module 70. The cooling station module may be used to control wafer temperature between individual process sequences. For example, the cooling station module may be used to cool the wafer substrate after the pretreatment (e.g., in the pre-sputter module), after the off-axis deposition, after the longitudinal deposition, or a combination thereof. The cooling station module may be used to cool the wafer substrate to room temperature (e.g., to about 25° C.). The cooling station may include a mechanism, such as an electrostatic or mechanical clamping system, for securing a wafer substrate in place. The cooling station may further include a system for applying a gas to the wafer substrate (e.g., to the backside of the wafer substrate) for improved thermal contact.

According to an embodiment, the cooling station module includes:
a. Wafer stage with electrostatic or mechanical clamping.
b. Wafer stage with backside gas capability for improved thermal contact.
c. Controlled cooling to room temperature.

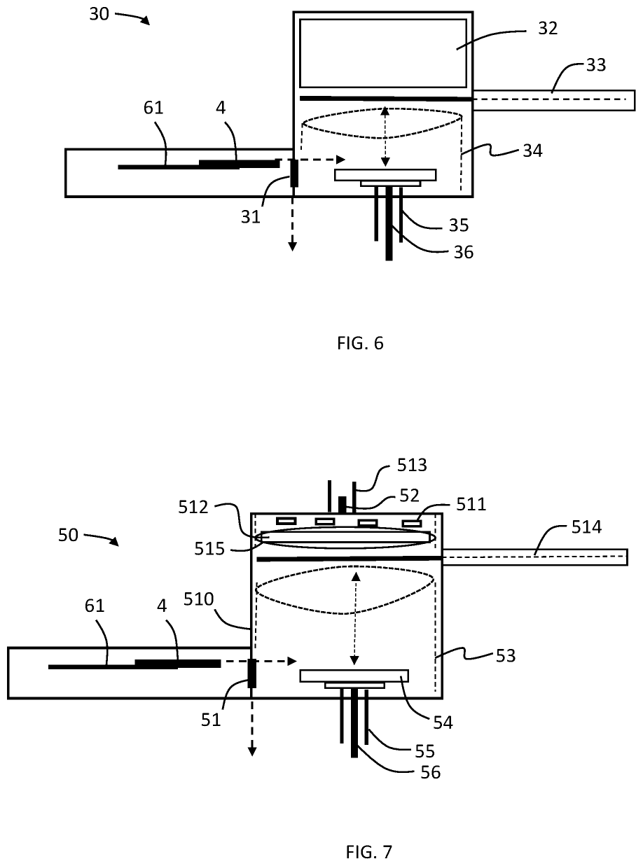

According to an embodiment, the system 1 includes a pre-sputter module 30. A schematic cross-sectional view of an exemplary pre-sputter module 30 is shown in FIG. 6. The robot arm 61 of the central wafer transfer unit 10 may deliver the wafer 4 to the pre-sputter module 30 through the access port 31. The pre-sputter module may be used to clean a wafer substrate (e.g., to prepare the surface of the electrode) prior to deposition in the off-axis module or longitudinal module. For example, the pre-sputter module may be used to remove absorbed gases or oxidation on the surface of the wafer substrate, and/or to affect the roughness of the surface. Adjusting the extent of pre-sputter surface preparation can be used to affect the growth of the subsequent deposited film. The pre-sputter module may include a plasma source and a capability to vary the distance of the plasma source to the wafer substrate. The plasma source may include an ICP/RF coil 32 with low ion energy, arranged to oppose the surface of the wafer substrate. The pre-sputter module 30 may include a shutter 33, as shown in FIG. 6. A stage control mechanism 36 may include an electrostatic or mechanical clamping system for securing a wafer substrate in place. The pre-sputter module may further include a gas supply 35 to the wafer substrate (e.g., to the backside of the wafer substrate) for improved thermal contact. The pre-sputter module 30 may further include features to monitor and control the temperature inside the module, such as internal shielding 34 and a temperature monitor and controls. The pre-sputter module may include the capability to bias (e.g., RF bias) the wafer substrate for cleaning. The RF bias may be, for example, 300 W or less. In some embodiments, the RF bias is 50 W or more, or 100 W or more. The RF bias may be from 50 W to 300 W, or from 100 W to 300 W. The wafer substrate may be heated to up to 400° C. for degassing and pre-heating in order to remove surface contaminants prior to depositing steps (e.g., in the off-axis module and the longitudinal module).

According to an embodiment, the pre-sputter/degas module includes:
a. Plasma source (ICP/RF coil-low frequency) with low ion energy opposing the wafer stage for pre-sputter cleaning.
b. Capability to vary plasma source to wafer stage distance to optimize pre-sputter cleaning.
c. Wafer stage with electrostatic or mechanical clamping.
d. Wafer stage with backside gas capability for improved thermal contact.
e. Wafer stage with RF bias (300 W or less) for pre-sputter cleaning.
f. Wafer stage with substrate heating up to 400° C. for degas and pre-heating.

The system 1 may include two or more deposition modules. According to an embodiment, the two or more deposition modules include at least an off-axis module 40 and a longitudinal module 50. The two or more deposition modules may include two (or more) off-axis modules. The off-axis deposition tends to be the slowest part of the process and having two off-axis modules allows for more efficient use of the system as a whole by eliminating a bottle neck.

According to an embodiment, the off-axis module 40 is configured for depositing material at an inclined c-axis. The off-axis module includes a linear sputtering apparatus with a magnetron and a target surface configured to eject metal atoms, a collimator, and a wafer chuck for holding and translating the wafer substrate within the module. The various parts of the off-axis module may be housed inside a chamber. The system may include a vacuum pump for drawing and maintaining a vacuum inside the chamber. The chamber may be separated from the central wafer transfer unit by a gate valve. The collimator assembly and the configuration of the collimator and magnetron in relation to the substrate are described in U.S. Pat. Nos. 9,922,809 and 10,541,663.

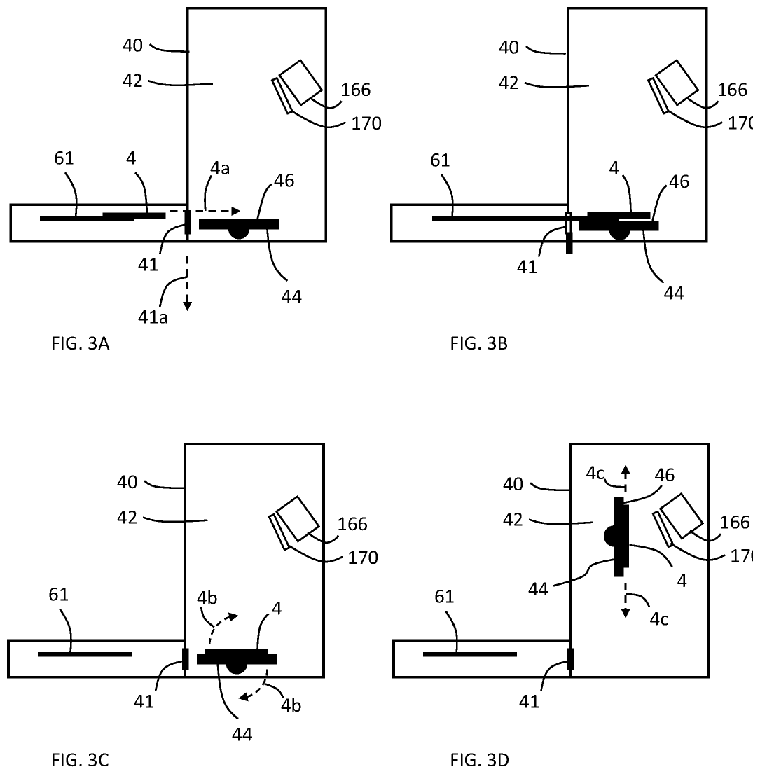

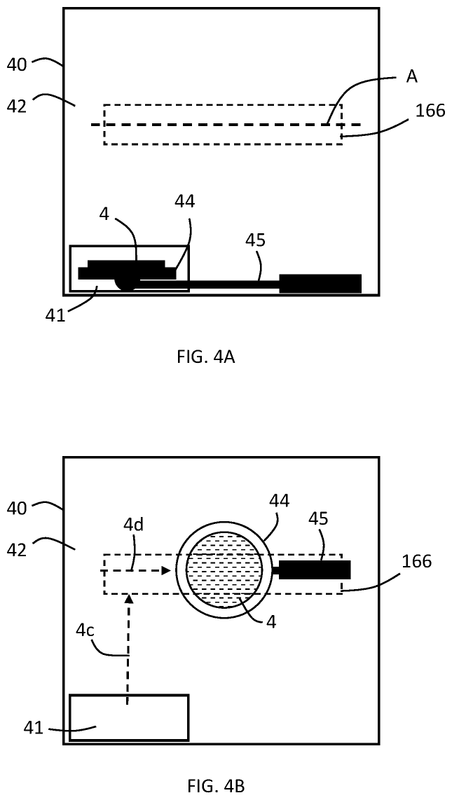

The delivery of the wafer substrate 4 by the robot arm 61 to the wafer chuck 44, and the operation of the wafer chuck 44 are schematically shown in FIGS. 3A-3D, which are cross-sectional side views of the robot arm and off-axis module 40, and FIGS. 4A and 4B, which are cross-sectional front views of the off-axis module 40. The robot arm 61 of the central wafer transfer unit 10 may deliver the wafer 4 to the off-axis module 40 through the access port 41, as shown in FIGS. 3A and 3B. The access port 41 may be opened, for example, by moving along arrow 41a. The wafer chuck 44 may include a support surface 46 that receives the wafer substrate 4. The wafer substrate 4 may lay flat on (e.g., be parallel to) the support surface 46. The wafer chuck 44 may be constructed to receive the wafer substrate 4 in a horizontal position, as shown in FIGS. 3A and 3B. That is, the robot arm 61 of the central wafer transfer unit 10 may deliver the wafer 4 to the off-axis module 40 in a horizontal position (e.g., where the wafer substrate 4 is disposed substantially horizontally). Horizontal movement of the wafer 4 is shown by arrow 4a. The wafer chuck 44 may be constructed to rotate the wafer substrate 4 within the off-axis module 40 to a non-horizontal position, such as a vertical position, as indicated by arrows 4b in FIG. 3C and shown in FIG. 3D. The support surface 46 and thus the wafer substrate 4 supported by the support surface 46 may be disposed along a vertical plane. The wafer chuck 44 may further be constructed to translate the wafer substrate 4 in the non-horizontal (e.g., vertical) position within the off-axis module 40. For example, the wafer chuck 44 may be constructed to ratchet the wafer substrate 4 up and down along a vertical plane, as indicated by arrows 4c. The wafer chuck 44 may also be constructed to translate the wafer substrate 4 side to side along the vertical plane. The vertical plane of the support surface may be non-parallel to the plane of the target surface of the sputtering apparatus. According to an embodiment, the target 166 has a longitudinal axis that is oriented along a horizontal line. The collimator assembly 170 may be arranged between the target 166 and the wafer substrate 4. The collimator assembly 170 may be oriented at an angle that is non-parallel with each of the target 166 and the wafer substrate 4.

FIGS. 4A and 4B are cross-sectional front views of the off-axis module 40, showing the wafer substrate 4 delivered to the wafer chuck 44 prior to rotating (FIG. 4A), and after rotating and moving (FIG. 4B). The wafer chuck 44 may be coupled with an arm 45 that rotates the wafer chuck 44. The arm 45 may further be configured to move (e.g., translate) the wafer chuck 44 and wafer substrate 4 in a vertical direction (arrow 4c) and a horizontal direction (arrow 4d), as shown in FIG. 4B, to position the wafer substrate 4 for deposition. The position of the target 166 is shown schematically in front of the wafer 4. The target 166 may extend along a longitudinal axis A. The longitudinal axis of the target 166 may be oriented along a horizontal line. The target 166 may be tilted such that the target surface is non-parallel to the wafer 4.

The off-axis module may include a linear magnetron with a sputtering cathode operatively coupled to a target surface to promote ejection of metal atoms from the target surface. The linear sputtering apparatus may include a rectangular magnetron. The magnetron may have a width of less than 5 inches (about 12.5 cm) to simulate a single point sputter source. In one example, the magnetron has a width of 3.11 inches (about 7.9 cm). The target surface of the sputtering apparatus may be arranged at an angle relative to the wafer substrate received in the chuck. For example, the target surface may be arranged non-parallel to the support surface for receiving the wafer substrate. According to an embodiment, the target has a longitudinal axis that is oriented along a horizontal line. A gas inlet may be provided to supply gas (e.g., argon and nitrogen) into the sputtering device.

The collimator of the off-axis module may include a plurality of guide members defining a plurality of collimator apertures arranged between the linear sputtering apparatus and the wafer chuck. The collimator may be movable within the module. For example, the collimator may be linearly translatable in a direction substantially parallel to the target surface. In one embodiment, the collimator is linearly translatable in a horizontal direction. The collimator may be arranged between the target surface and the wafer substrate. The collimator may be oriented at an angle that is non-parallel with each of the target surface and the wafer substrate.

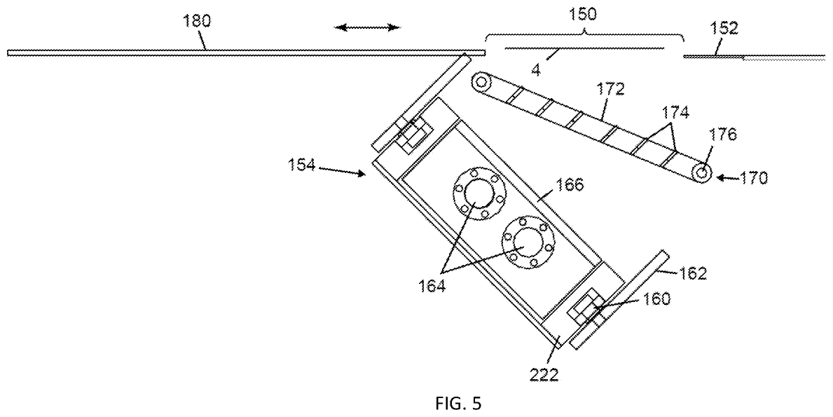

The arrangement of the linear sputtering apparatus, collimator, and wafer substrate are schematically shown in FIG. 5, which is a downward-facing cross-sectional view of a portion of the off-axis reactor. As shown, a wafer substrate 4 is arranged proximate to a deposition aperture 150 (bounded in part by a shield panel 180 and a uniformity shield 152), with the collimator assembly 170 intermediately arranged between the wafer substrate 4 and the linear sputtering apparatus 154. In certain embodiments, the deposition aperture 150 includes a width ranging from about 3 inches to about 9 inches. The uniformity shield 152 may extend into the deposition aperture 150 and have a maximum width of about 2 inches. An ejection surface of the target 166 is arranged along a front surface of the linear sputtering apparatus 154. The collimator assembly 170 is arranged between the target 166 and the wafer substrate 4 at an angle that is non-parallel with each of the target 166 and the wafer substrate 4. The collimator assembly 170 includes multiple horizontal guide members 172 and vertical guide members 174 that in combination form a grid. The grid defines multiple apertures that permit passage of metal atoms ejected by a surface of the target 166. The collimator assembly 170 is further bounded laterally by tubular supports 176. The linear sputtering apparatus 154 may include liquid ports 164 configured to circulate liquid. The collimator assembly 170 may be configured to move (e.g., translate) in a vertical direction. The linear sputtering apparatus 154 may include channel guides 222 arranged to receive bearings 160 and to support collimator side brackets 162 that permit the collimator assembly 170 to move.

The off-axis module may have the capability to vary the distance between the target and the wafer. For example, the distance between the target and the wafer may be varied to optimize uniformity of the deposited film thickness. The uniformity of the resulting film across the wafer may also be improved by using a shaper system at the wafer aperture.

The off-axis module may include a mechanism, such as an electrostatic or mechanical clamping system, for securing a wafer substrate in place. The off-axis module may further include a gas supply for supplying gas to the wafer substrate (e.g., to the backside of the wafer substrate) for improved thermal contact. The off-axis module may include the capability to bias (e.g., RF bias) the wafer substrate for cleaning. The RF bias may be, for example, 300 W or less. In some embodiments, the RF bias is 50 W or more, or 100 W or more. The RF bias may be from 50 W to 300 W, or from 100 W to 300 W. The wafer substrate may be heated to up to 400° C. during deposition. The off-axis module may further include features to monitor and control the temperature inside the module, such as internal shielding and a temperature monitor and controls, for improved process stability during deposition.

In some embodiments the system includes more than one off-axis module. For example, the system may include two or three off-axis modules. The two or more off-axis modules may have the same or substantially same configuration as described herein.

According to an embodiment, the off-axis module includes:

a. A configuration as described in U.S. Pat. Nos. 9,922,809 and 10,541,663 with regard to:
1. Collimator assembly and motion;
2. Collimator/magnetron/substrate configuration;
3. Rectangular magnetron; and
4. Substrate motion.

b. Wafer orientation face down or vertical to reduce particulate contamination associated with collimator.

c. Capability to vary target to wafer stage distance to optimize thickness uniformity.

d. Rectangular magnetron with a width of less than 5 inches to simulate a single point sputter source. Process may be established with a 3.11 inch wide magnetron.

e. Wafer aperture with shaper system to minimize thickness non-uniformity across wafer.

f. Wafer stage with electrostatic or mechanical clamping.

g. Wafer stage with backside gas capability for improved thermal contact.

h. Wafer stage with RF bias (300 W or less) to control as deposited film stress.

i. Wafer stage with substrate heating up to 400° C. for substate temperature control during deposition.

j. Internal shielding, temperature monitoring, and control for improved process stability during deposition.

According to an embodiment, the system further includes a longitudinal module. A schematic cross-sectional view of an exemplary longitudinal module 50 is shown in FIG. 7. The longitudinal module 50 is configured for depositing material at a normal incidence (e.g., perpendicular to the wafer substrate surface). The longitudinal module includes a circular sputtering apparatus with a magnetron 511 with a sputtering cathode operatively coupled to a target surface 512 configured to eject metal atoms for deposition onto the wafer substrate. The longitudinal module may include a wafer chuck 54 for holding and translating the wafer substrate within the module. The robot arm 61 of the central wafer transfer unit 10 may deliver the wafer 4 to the wafer chuck 54 of the longitudinal module 50 through the access port 51. The wafer substrate 4 may lay flat on (e.g., be parallel to) the support surface of the wafer chuck 54. A gas inlet 513 may be provided to supply gas (e.g., argon and nitrogen) into the sputtering device. Motor 52 may be used to rotate the magnets. The module may also include a shutter 514. The various parts of the longitudinal module 50 may be housed inside a chamber 510. The system may include a vacuum pump for drawing and maintaining a vacuum inside the chamber. The chamber may be separated from the central wafer transfer unit by a gate valve 51. According to an embodiment, the longitudinal module does not include a collimator.

The longitudinal module may have the capability to vary the distance between the target and the wafer. For example, the distance between the target and the wafer may be varied, e.g., stage control mechanism 56 to optimize uniformity of the deposited film thickness. The uniformity of the resulting film across the wafer may also be improved by using a shaper system at the wafer aperture.

The longitudinal module may include a stage control mechanism 55, which may include an electrostatic or mechanical clamping system for securing the wafer substrate in place. The longitudinal module may further include a gas supply 56 for applying a gas to the wafer substrate (e.g., to the backside of the wafer substrate) for improved thermal contact. The longitudinal module may include the capability to bias (e.g., RF bias) the wafer substrate for cleaning. The RF bias may be, for example, 300 W or greater. The wafer substrate may be heated to up to 400° C. during deposition. The longitudinal module may include a DC coil 515 arranged in the proximity of the circular target to control plasma uniformity from the magnetron. The longitudinal module may further include features to monitor and control the temperature inside the module, such as internal shielding 53 and a temperature monitor and controls, for improved process stability during deposition.

According to an embodiment, the longitudinal module includes:

a. Circular magnetron.

b. Capability to vary target to wafer stage distance to optimize thickness uniformity.

c. Wafer stage with electrostatic or mechanical clamping.

d. Wafer stage with backside gas supply for improved thermal contact.

e. Wafer stage with RF bias (300 W or greater) to control as deposited film stress.

f. Wafer stage with substrate heating up to 400° C. for substate temperature control during deposition.

g. DC coil in the proximity of the circular target to control magnetron plasma uniformity.

h. Internal shielding, temperature monitoring, and control for improved process stability during deposition.

The system may include any suitable control unit operatively connected to the central wafer transfer unit and the various modules. For example, the system may include a central computer and optionally individual module computers that handle the operation of the various modules, where the central computer is operatively connected to each of the individual module computers. The central computer may include a graphic user interface (GUI) for handling and controlling the system and the individual module computers. The control unit may be programmed to enable cluster structuring and to improve uptime of the system.

In one embodiment, the system control architecture includes:

a. Central computer for handling and GUI coupled with individual module computers that enables cluster structuring and improved uptime

The exact configuration of the controller of the system is not limiting, and essentially any device capable of providing suitable computing capabilities and control capabilities to implement the method may be used. In view of the above, it will be readily apparent that the control functionality may be implemented in any manner as would be known to one skilled in the art. As such, the computer language, the controller, or any other software/hardware which is to be used to implement the processes described herein shall not be limiting on the scope of the systems, processes, or programs (for example, the functionality provided by such processes or programs) described herein. The methods and processes described in this disclosure, including those attributed to the systems, or various constituent components, may be implemented, at least in part, in hardware, software, firmware, or any combination thereof. For example, various embodiments of the techniques may be implemented within one or more processors, including one or more microprocessors, DSPs, ASICs, FPGAs, CPLDs, microcontrollers, or any other equivalent integrated or discrete logic circuitry, as well as any combinations of such components. When implemented in software, the functionality ascribed to the systems, devices, and methods described in this disclosure may be embodied as instructions on a computer-readable medium such as RAM, ROM, NVRAM, EEPROM, FLASH memory, magnetic data storage media, optical data storage media, or the like. The instructions may be executed by one or more processors to support one or more embodiments of the functionality.

According to an embodiment, the system may be used to deposit material onto a wafer substrate. A method of using the system to deposit material may include one or more of the following steps: loading the wafer substrate to a load lock; retrieving a wafer substrate from a cassette elevator; transferring the wafer substrate from the load lock to a central wafer transfer unit; transferring the wafer substrate from the central wafer transfer unit into a pre-sputter module and cleaning the wafer substrate by plasma sputter; transferring the wafer substrate to an off-axis module and depositing material onto the wafer substrate at an inclined c-axis; and transferring the wafer substrate from the central wafer transfer unit to a longitudinal module and depositing material onto the wafer substrate at normal incidence. Transferring of the wafer substrate may be done by a robot arm. The robot arm may transfer the wafer substrate in a horizontal position.

The method may include creating a vacuum within the central wafer transfer unit and one or more of the modules, such as the pre-sputter module, the off-axis module, and the longitudinal module. The vacuum may be separately controlled within each of the modules, which may be separated from the central wafer transfer unit by gate valves. The temperature of the wafer substrate may be controlled by cooling, heating, or a combination thereof, within each of the modules. The load lock may act as an intermediate transfer environment, where the vacuum is lower than atmospheric but somewhat higher than the central wafer transfer unit or the individual modules. For example, the load lock may have a pressure in the range of 1·10⁻⁴ Torr to 1·10⁻⁸ Torr, or from 1·10⁻⁶ Torr to 1·10⁻⁷ Torr. The pressure in the central wafer transfer unit may be in the range of 1·10⁻⁷ Torr to 1·10⁻⁸ Torr. The pressure within the deposition modules (e.g., off-axis module and longitudinal module) may be in the range of 5·10⁻⁹ Torr to 1·10⁻² Torr. The sputtering may be performed in an argon and nitrogen atmosphere controlled within individual modules.

The robot arm may transfer the wafer substrate to the off-axis module in a horizontal position and deliver the wafer substrate to a wafer chuck inside the off-axis module. The wafer chuck may then rotate the wafer substrate to a vertical position (e.g., where a main surface of the wafer substrate is arranged along a vertical plane). The wafer chuck may translate the wafer substrate in the vertical position along a vertical plane or a vertical line.

The method may include ejecting metal atoms from a target surface using a linear magnetron with a sputtering cathode. The vertical plane of the support surface may be non-parallel to the plane of the target surface of the sputtering apparatus. In an embodiment, the target surface of the sputtering apparatus is disposed along a horizontal line. According to an embodiment, the method includes depositing material onto the wafer substrate at an inclined c-axis. Depositing material at an inclined c-axis may include depositing a seed layer directly onto the wafer substrate.

The method may include transferring the wafer substrate from the off-axis module into the longitudinal module and receiving the wafer substrate in the wafer chuck of the longitudinal module. The method may further include depositing material using the longitudinal module, by ejecting metal atoms from the target surface of a circular sputtering apparatus. Depositing material using the longitudinal module may include depositing a bulk layer onto the seed layer deposited in the off-axis module. The material (e.g., the bulk layer) may be deposited at a normal incidence.

In embodiments where the system includes two or more off-axis modules, the longitudinal module may receive wafer substrates alternatingly from the two or more off-axis modules. This may help avoid downtime of the longitudinal module and streamline production within the system. For example, while material is deposited onto one wafer substrate in the first off-axis module, a second wafer substrate may be transferred from the central wafer transfer unit to a second off-axis module for depositing material onto the second wafer substrate.

In one or more embodiments, the system may be described as being implemented using one or more computer programs executed on one or more programmable processors that include processing capabilities (for example, microcontrollers or programmable logic devices), data storage (for example, volatile or non-volatile memory or storage elements), input devices, and output devices. Program code, or logic, described herein may be applied to input data to perform functionality described herein and generate desired output information. The output information may be applied as input to one or more other devices or processes as described herein or as would be applied in a known fashion.

The computer program products used to implement the processes described herein may be provided using any programmable language, for example, a high-level procedural or object orientated programming language that is suitable for communicating with a computer system. Any such program products may, for example, be stored on any suitable device, for example, a storage media, readable by a general or special purpose program, controller apparatus for configuring and operating the computer when the suitable device is read for performing the procedures described herein. In other words, at least in one embodiment, the system may be implemented using a non-transitory computer readable storage medium, configured with a computer program, where the storage medium so configured causes the computer to operate in a specific and predefined manner to perform functions described herein.

The system and method of the present disclosure may be used to fabricate bulk acoustic wave resonator structures. The bulk acoustic wave resonator structures include a bulk layer with inclined c-axis hexagonal crystal structure material (e.g., piezoelectric material). The hexagonal crystal structure bulk layer is supported by a substrate. The bulk layer may be formed in a two-step process, where the first step is performed in the off-axis module and the second step is performed in the longitudinal module. In the first step a first portion of the layer (e.g., a seed layer) is deposited at an off-normal angle of incidence to achieve a desired c-axis tilt. Once the c-axis tilt is established, the remainder of the layer (e.g., the bulk layer) is deposited at normal incidence. Despite being deposited at normal incidence, the remaining bulk layer tends to adopt the c-axis tilt of the previously deposited crystal layer. Such processes may be performed without the use of a traditional seed layer which tends to promote (103) texture with no in-plane alignment along the (002) direction. Alternatively, the processes may be performed using a traditional seed layer.

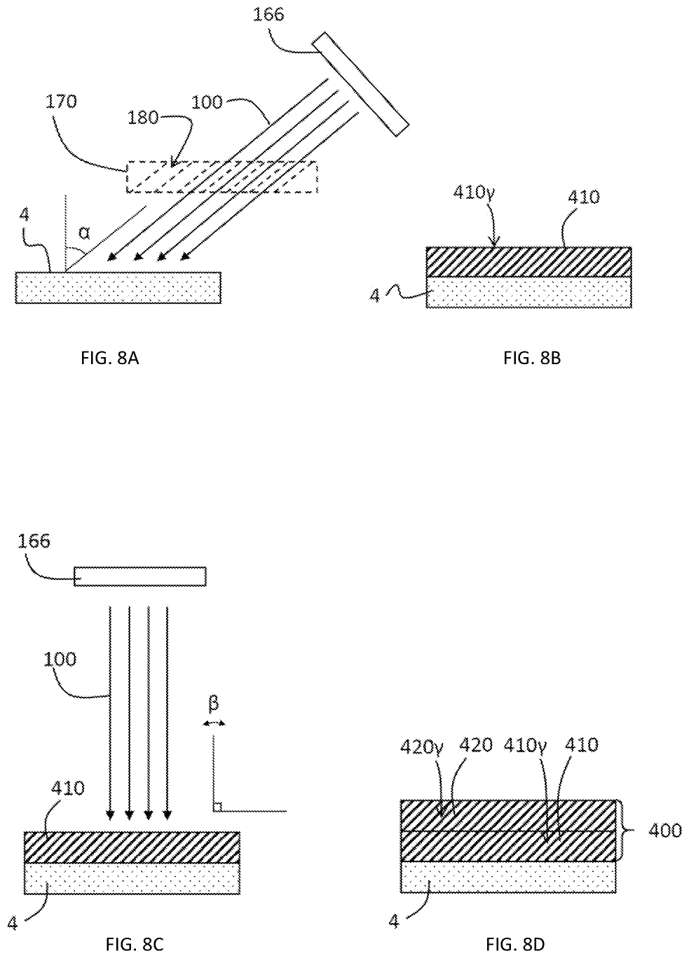

Referring now to FIGS. 8A-8D, schematic diagrams for two-step bulk layer deposition processes are shown. The first growth step (shown in FIG. 8A) includes ejection of metal atoms from a target 166 of a linear sputtering apparatus in an off-axis module to react with a gas species forming a deposition flux 100 to be received by the substrate 4. The off-axis module may include a multi-aperture collimator 170 arranged between the target and the substrate. The deposition flux 100 may be directed through the apertures 180 of the collimator 170 to help control the incidence angle during deposition. The deposition flux 100 arrives at the substrate 4 at a first incidence angle α, forming a first portion 410 (e.g., seed layer) of the film 400 (shown in FIG. 8B). The crystals of the first portion 410 of the film 400 have a c-axis tilt 410y.

In a second growth step (shown in FIG. 8C), metal atoms are ejected from target 166 in a longitudinal module to react with a gas species and to be received by the first portion 410 already deposited on the substrate 4. In the second growth step, the target 166 may be positioned such that the second incidence angle θ is smaller than the first incidence angle α (e.g., is between normal and the first incidence angle α). For example, the second incidence angle θ may be about 0 degrees (i.e., normal to the surface of the substrate 4). The deposition flux 100 in the second growth step form a second portion 420 (e.g., bulk layer) of the film 400 (shown in FIG. 8D). The crystals of the second portion 420 of the film 400 have a c-axis tilt 420y. The second growth step may be done without a collimator.

According to an embodiment, the c-axis tilt 420y of the second portion 420 (e.g., the bulk layer) follows or substantially follows the c-axis tilt 410y of the first portion 410 of the film 400. In some embodiments, the c-axis tilt 410y, 420y of the first and second portions 410, 420 aligns or at least substantially aligns with the first incidence angle α used during the first growth step. The resulting bulk layer crystals of the first portion 410 and second portion 420 may be substantially parallel to one another and at least substantially align with the desired c-axis tilt. The resulting crystals of the first portion 410 and second portion 420 may also be substantially parallel within each portion. For example, at least 50%, at least 75%, or at least 90% of the crystals of the first portion 410 may have a c-axis tilt 410y that is within 0 degrees to 10 degrees of the average c-axis tilt, and a direction that is within 0 degrees to 45 degrees, or within 0 degrees to 20 degrees of the average crystal direction. Similarly, at least 50%, at least 75%, or at least 90% of the crystals of the second portion 420 may have a c-axis tilt 420y that is within 0 degrees to 10 degrees of the average c-axis tilt, and a direction that is within 0 degrees to 45 degrees, or within 0 degrees to 20 degrees of the average crystal direction.

In some embodiments, a structure includes a substrate comprising a wafer or a portion thereof; and a piezoelectric bulk material layer having a first portion (e.g., seed layer) deposited onto the substrate and a second portion (e.g., bulk layer) deposited onto the first portion, the second portion having an outer surface having a surface roughness (Ra) of 4.5 nm or less. The piezoelectric bulk material layer may have a c-axis tilt of about 35 degrees to about 52 degrees. The crystalline bulk layer may exhibit a ratio of shear piezoelectric coupling coefficient to longitudinal piezoelectric coupling coefficient (referred to here as the ratio of shear coupling to longitudinal coupling) of 1.25 or greater during excitation.

The structure may include a bump disposed at least partially on the bulk material layer. According to an embodiment, the bump contact may exhibit a shear strength that can resist forces of 80 g or greater, 100 g or greater, 110 g or greater, 120 g or greater, 130 g or greater, or 140 g or greater.

The bulk material layer may have a thickness of about 1,000 Angstroms to about 30,000 Angstroms. The thickness may vary by less than 2% over an area of the bulk material layer.

In some embodiments, a crystalline bulk layer having a c-axis tilt with a preselected angle is prepared by a method that includes deposition of a first portion in a first growth step using the off-axis module under deposition conditions comprising a pressure of 5 mTorr or less. The first growth step is performed at off-normal incidence. Preferably, the deposited layer has a c-axis tilt of about 35 degrees or greater. For example, the layer may be deposited at a deposition angle of about 35 degrees to about 85 degrees. Preferably, the deposition in the first growth step is under conditions that retard surface mobility of the material being deposited such that crystals in the bulk material layer are substantially parallel to one another and are substantially oriented in a direction of the preselected angle. The method further comprises deposition of a second portion in a second growth step using the longitudinal module, including depositing a bulk material layer at a smaller incidence angle, e.g., at about a normal incidence. Despite being deposited at about normal incidence, the second portion of the layer deposited in the second growth step orients to the c-axis tilt of the first portion, e.g., about 35 degrees or greater. The bulk material may exhibit a ratio of shear coupling to longitudinal coupling of 1.25 or greater during excitation. The bulk layer (e.g., the second portion) may have an outer surface having a surface roughness (Ra) of 4.5 nm or less.

In various embodiments described herein, the bulk layer is prepared such that the c-axis orientation of the crystals in the bulk layer is selectable within a range of about 0 degrees to about 90 degrees, such as from about 30 degrees to about 52 degrees, or from about 35 degrees to about 46 degrees. The c-axis orientation distribution is preferably substantially uniform over the area of a large substrate (e.g., having a diameter in a range of at least about 50 mm or greater, about 100 mm or greater, or about 150 mm or greater), thereby enabling multiple chips to be derived from a single substrate and having the same or similar acoustic wave propagation characteristics.

In various embodiments described herein, the bulk material layer (including the seed layer and the bulk layer) deposited using the system and method of the present disclosure has a thickness of about 1,000 Angstroms to about 30,000 Angstroms. The bulk material layer may be deposited at a deposition angle of about 35 degrees to about 85 degrees. The bulk material may exhibit a ratio of shear coupling to longitudinal coupling of 1.25 or greater during excitation.

In various embodiments described herein, a structure prepared using the system and method of the present disclosure includes a substrate comprising a wafer and a piezoelectric bulk material layer deposited onto a surface of the wafer, where the bulk material layer has a c-axis tilt of about 32 degrees or greater. The structure may exhibit a ratio of shear coupling to longitudinal coupling of 1.25 or greater during excitation. The bulk layer (e.g., the second portion) may have an outer surface having a surface roughness (Ra) of 4.5 nm or less.

In various embodiments described herein, a bulk acoustic wave resonator prepared using the system and method of the present disclosure includes a structure including a substrate comprising a wafer and a piezoelectric bulk material layer deposited onto a surface of the wafer, where the bulk material layer has a c-axis tilt of about 32 degrees or greater, where at least a portion of piezoelectric bulk material layer is between the first electrode and the second electrode. The bulk layer (e.g., the second portion) may have an outer surface having a surface roughness (Ra) of 4.5 nm or less.

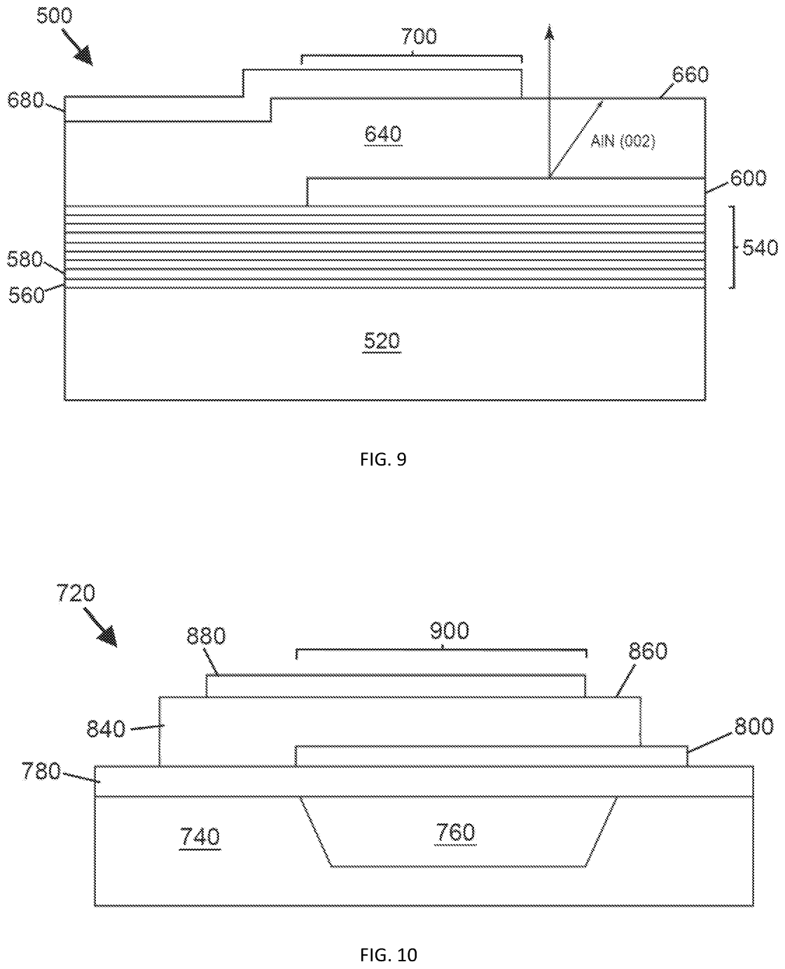

The piezoelectric material films with a bulk layer made according to embodiments of the present disclosure can be used in various bulk acoustic wave (“BAW”) devices, such as BAW resonators. Exemplary BAW resonators employing the piezoelectric material films of the present disclosure are shown in FIGS. 9 and 10.

FIG. 9 is a schematic cross-sectional view of a portion of a bulk acoustic wave solidly mounted resonator device 500 including a piezoelectric material bulk layer 640 embodying an inclined c-axis hexagonal crystal structure piezoelectric material (e.g., AlN or ZnO) as disclosed herein. The c-axis (or (002) direction) of the piezoelectric material bulk layer 640 is tilted away from a direction normal to the substrate 520, as illustrated by two arrows superimposed over the piezoelectric material bulk layer 640. The resonator device 500 includes the substrate 520 (e.g., typically silicon or another semiconductor material), an acoustic reflector 540 arranged over the substrate 520, the piezoelectric material bulk layer 640, and bottom and top side electrodes 600, 680. The bottom side electrode 600 is arranged between the acoustic reflector 540 and the piezoelectric material bulk layer 640, and the top side electrode 680 is arranged along a portion of an upper surface 660 of the piezoelectric material bulk layer 640. An area in which the piezoelectric material bulk layer 640 is arranged between overlapping portions of the top side electrode 680 and the bottom side electrode 600 is considered the active region 700 of the resonator device 500. The acoustic reflector 540 serves to reflect acoustic waves and therefore reduce or avoid their dissipation in the substrate 520. In certain embodiments, the acoustic reflector 540 includes alternating thin layers 560, 580 of materials of different acoustic impedances (e.g., SiOC, Si₃N₄, SiO₂, AlN, and Mo), optionally embodied in a Bragg mirror, deposited over the substrate 520. In certain embodiments, other types of acoustic reflectors may be used. Steps for forming the resonator device 500 may include depositing the acoustic reflector 540 over the substrate 520, followed by deposition of the bottom side electrode 600, followed by growth (e.g., via sputtering or other appropriate methods) of the piezoelectric material bulk layer 640, followed by deposition of the top side electrode 680.

FIG. 10 is a schematic cross-sectional view of a film bulk acoustic wave resonator (FBAR) device 720 according to one embodiment. The FBAR device 720 includes a substrate 740 (e.g., silicon or another semiconductor material) defining a cavity 760 that is covered by a support layer 780 (e.g., silicon dioxide). A bottom side electrode 800 is arranged over a portion of the support layer 780, with the bottom side electrode 800 and the support layer 780. A piezoelectric material bulk layer 840 embodying inclined c-axis hexagonal crystal structure piezoelectric material (e.g., AlN or ZnO) is arranged over the bottom side electrode 800, and a top side electrode 880 is arranged over at least a portion of a top surface 860 of the piezoelectric material bulk layer 840. A portion of the piezoelectric material bulk layer 840 arranged between the top side electrode 880 and the bottom side electrode 800 embodies an active region 900 of the FBAR device 720. The active region 900 is arranged over and registered with the cavity 760 disposed below the support layer 780. The cavity 760 serves to confine acoustic waves induced in the active region 900 by preventing dissipation of acoustic energy into the substrate 740, since acoustic waves do not efficiently propagate across the cavity 760. In this respect, the cavity 760 provides an alternative to the acoustic reflector 540 illustrated in FIG. 9. Although the cavity 760 shown in FIG. 10 is bounded from below by a thinned portion of the substrate 740, in alternative embodiments at least a portion of the cavity 760 extends through an entire thickness of the substrate 740. Steps for forming the FBAR device 720 may include defining the cavity 760 in the substrate 740, filling the cavity 760 with a sacrificial material (not shown) optionally followed by planarization of the sacrificial material, depositing the support layer 780 over the substrate 740 and the sacrificial material, removing the sacrificial material (e.g., by flowing an etchant through vertical openings defined in the substrate 740 or the support layer 780, or lateral edges of the substrate 740), depositing the bottom side electrode 800 over the support layer 780, growing (e.g., via sputtering or other appropriate methods) the piezoelectric material bulk layer 840, and depositing the top side electrode 880.

In certain embodiments, an acoustic reflector structure is arranged between the substrate and the at least one first electrode structure to provide a solidly mounted bulk acoustic resonator device. Optionally, a backside of the substrate may include a roughened surface configured to reduce or eliminate backside acoustic reflection. In other embodiments, the substrate defines a recess, a support layer is arranged over the recess, and the support layer is arranged between the substrate and at least a portion of the at least one first electrode structure, to provide a film bulk acoustic wave resonator structure.

The following is a list of exemplary embodiments of the present disclosure:

Embodiment 1 is a system for depositing material onto a substrate, the system comprising: two or more process modules comprising: an off-axis module constructed to deposit material at an inclined c-axis; and a longitudinal module constructed to deposit material at normal incidence. The system further comprises a central wafer transfer unit comprising a load lock, a vacuum chamber, and a robot disposed within the vacuum chamber and constructed to transfer a wafer substrate between the central wafer transfer unit and the two or more process modules; and a control unit operatively connected to the robot.

Embodiment 2 is the system of embodiment 1, wherein the central housing unit comprises a cooling station constructed to control wafer temperature. In some embodiments the cooling station module is used to cool the wafer substrate after the pretreatment (e.g., in the pre-sputter module), after the off-axis deposition, after the longitudinal deposition, or a combination thereof. In an embodiment, the cooling station module cools the wafer substrate to room temperature (e.g., to about 25° C.). In an embodiment, the cooling station includes a mechanism, such as an electrostatic or mechanical clamping system, for securing a wafer substrate in place. In an embodiment, the cooling station includes a system for applying a gas to the wafer substrate (e.g., to the backside of the wafer substrate) for improved thermal contact.

Embodiment 3 is the system of embodiment 1 or 2, wherein the two or more process modules comprise a pre-sputter module constructed to prepare wafer substrates for deposition of material. In an embodiment, the pre-sputter module is constructed to remove absorbed gases or oxidation on the surface of the wafer substrate, and/or to affect the roughness of the surface.

Embodiment 4 is the system of embodiment 3, wherein the pre-sputter module comprises a plasma sputtering device. In an embodiment, the pre-sputter module comprises an ICP/RF coil with low ion energy, arranged to oppose the surface of the wafer substrate. In an embodiment, the pre-sputter module comprises a stage control mechanism, optionally with an electrostatic or mechanical clamping system for securing a wafer substrate in place.

Embodiment 5 is the system of embodiment 3 or 4, wherein the pre-sputter module comprises a degassing unit, a wafer heater, or both. In an embodiment, the pre-sputter module comprises a gas supply to the wafer substrate (e.g., to the backside of the wafer substrate). for improved thermal contact. In an embodiment, the pre-sputter module comprises features to monitor and control the temperature inside the module, such as internal shielding and a temperature monitor and controls. In an embodiment, the pre-sputter module comprises the capability to bias (e.g., RF bias) the wafer substrate for cleaning. The RF bias may be, for example, 300 W or less. In some embodiments, the RF bias is 50 W or more, or 100 W or more. The RF bias may be from 50 W to 300 W, or from 100 W to 300 W. In an embodiment, the pre-sputter module is constructed to heat the wafer substrate to up to 400° C. for degassing and pre-heating.

Embodiment 6 is the system of any one of embodiments 1 to 5, wherein the central wafer transfer unit is positioned centrally between the two or more process modules.

Embodiment 7 is the system of any one of embodiments 1 to 6, wherein each of the two or more process modules comprises an internal environment that is controlled separately from the central wafer transfer unit.

Embodiment 8 is the system of any one of embodiments 1 to 7, wherein each of the two or more process modules is separated from the central housing unit by a valve.

Embodiment 9 is the system of any one of embodiments 1 to 8, wherein the robot is constructed to transfer the wafer substrate in a horizontal position.

Embodiment 10 is the system of any one of embodiments 1 to 9, wherein the off-axis module comprises a wafer chuck constructed to receive the wafer substrate.

Embodiment 11 is the system of embodiment 10, wherein the wafer chuck is constructed to receive the wafer substrate in a horizontal position and to rotate the wafer substrate to a vertical position.

Embodiment 12 is the system of embodiment 11, wherein the wafer chuck is constructed to translate the wafer substrate in the vertical position. In an embodiment, the wafer chuck is constructed to translate the wafer substrate in a horizontal direction. In an embodiment, the wafer chuck is constructed to translate the wafer substrate in a vertical direction.

Embodiment 13 is the system of any one of embodiments 1 to 12 further comprising a cassette elevator for housing a plurality of wafer substrates accessible by the robot.

Embodiment 14 is the system of embodiment 13, wherein the robot is constructed to retrieve a wafer substrate from the cassette elevator and to transfer the retrieved wafer substrate to one of the process modules.

Embodiment 15 is the system of any one of embodiments 1 to 14, wherein the off-axis module comprises a chamber, a vacuum pump constructed to create a vacuum in the chamber, and a linear sputtering apparatus housed within the chamber, wherein the chamber is separated from the central housing unit by a gate valve.

Embodiment 16 is the system of any one of embodiments 1 to 15, wherein the off-axis module comprises: a linear sputtering apparatus comprising a target surface configured to eject metal atoms; a wafer chuck comprising a support surface and configured to receive and secure in place a wafer substrate; and a collimator comprising a plurality of guide members defining a plurality of collimator apertures arranged between the linear sputtering apparatus and the wafer chuck. In an embodiment, the collimator is linearly translatable in a direction substantially parallel to the target surface. In an embodiment, the target surface is arranged non-parallel to the support surface.

Embodiment 17 is the system of embodiment 16, wherein the linear sputtering apparatus comprises a linear magnetron with a sputtering cathode operatively coupled to the target surface to promote ejection of metal atoms from the target surface. In an embodiment, the linear sputtering apparatus includes a rectangular magnetron. In an embodiment, the magnetron has a width of less than 5 inches (about 12.5 cm) to simulate a single point sputter source. In an embodiment, the magnetron has a width of 3.11 inches (about 7.9 cm).

Embodiment 18 is the system of embodiment 17, wherein the support surface is disposed along a vertical plane that is non-parallel to the target surface.

Embodiment 19 is the system of embodiment 18, wherein the target surface has a longitudinal axis that is oriented along a horizontal line.

Embodiment 20 is the system of embodiment 19, wherein the support surface is configured to ratchet up and down along its vertical plane.

Embodiment 21 is the system of any one of embodiments 1 to 20 further comprising a second off-axis module. In an embodiment, the system comprises a third off-axis module.

Embodiment 22 is the system of any one of embodiments 1 to 21, wherein the longitudinal module comprises a chamber, a vacuum pump constructed to create a vacuum in the chamber, and a circular sputtering apparatus housed within the chamber, wherein the chamber is separated from the central housing unit by a gate valve.

Embodiment 23 is the system of any one of embodiments 1 to 22, wherein the longitudinal module comprises: a circular sputtering apparatus comprising a target surface configured to eject metal atoms; and a wafer chuck comprising a support surface and configured to receive and secure in place a wafer substrate, wherein the target surface is arranged parallel to the support surface.

Embodiment 24 is a method of depositing material onto a substrate, the method comprising: transferring a wafer substrate from a load lock to a central wafer transfer unit; transferring the wafer substrate from the central wafer transfer unit to an off-axis module and depositing material onto the wafer substrate at an inclined c-axis; and transferring the wafer substrate from the central wafer transfer unit to a longitudinal module and depositing material onto the wafer substrate at normal incidence.

Embodiment 25 is the method of embodiment 24, wherein transferring the wafer substrate is done by a robot arm.

Embodiment 26 is the method of any one of embodiments 24 or 25 further comprising transferring the wafer substrate into a pre-sputter module and cleaning the wafer substrate by plasma sputter. In an embodiment, the cleaning comprises removing absorbed gases or oxidation on the surface of the wafer substrate, and/or changing the roughness of the surface.

Embodiment 27 is the method of any one of embodiments 24 to 26 further comprising controlling wafer temperature by cooling, heating, or a combination thereof.

Embodiment 28 is the method of any one of embodiments 24 to 27 further comprising creating a vacuum within the central wafer transfer unit, the off-axis module, and the longitudinal module.

Embodiment 29 is the method of any one of embodiments 24 to 28 further comprising transferring the wafer substrate in a horizontal position.

Embodiment 30 is the method of embodiment 29 further comprising receiving the wafer substrate on a wafer chuck in the off-axis module and rotating the wafer substrate to a vertical position.

Embodiment 31 is the method of embodiment 30 further comprising translating the wafer substrate in the vertical position. In an embodiment, the method comprises translating the wafer substrate in a horizontal direction. In an embodiment, the method comprises translating the wafer substrate in a vertical direction.

Embodiment 32 is the method of any one of embodiments 24 to 31 further comprising loading the wafer substrate from a cassette elevator to the load lock, wherein the cassette elevator houses a plurality of wafer substrates.

Embodiment 33 is the method of any one of embodiments 24 to 32, wherein the off-axis module comprises: a linear sputtering apparatus comprising a target surface configured to eject metal atoms; a wafer chuck comprising a support surface and configured to receive and secure in place a wafer substrate; and a collimator comprising a plurality of guide members defining a plurality of collimator apertures arranged between the linear sputtering apparatus and the wafer chuck, the collimator being linearly translatable in a direction substantially parallel to the target surface, wherein the target surface is arranged non-parallel to the support surface.

Embodiment 34 is the method of embodiment 33 further comprising using a linear magnetron with a sputtering cathode to promote ejection of metal atoms from the target surface. In an embodiment, the linear sputtering apparatus includes a rectangular magnetron. In an embodiment, the magnetron has a width of less than 5 inches (about 12.5 cm) to simulate a single point sputter source. In an embodiment, the magnetron has a width of 3.11 inches (about 7.9 cm).

Embodiment 35 is the method of embodiment 34, wherein the support surface is disposed along a vertical plane that is non-parallel to the target surface.

Embodiment 36 is the method of embodiment 35, wherein the target surface has a longitudinal axis that is oriented along a horizontal line.

Embodiment 37 is the method of embodiment 36 further comprising ratcheting the support surface up and down along its vertical plane.

Embodiment 38 is the method of any one of embodiments 24 to 37, wherein the depositing of material onto the wafer substrate at an inclined c-axis comprises depositing a seed layer.

Embodiment 39 is the method of any one of embodiments 24 to 38, wherein the longitudinal module comprises: a circular sputtering apparatus comprising a target surface configured to eject metal atoms; and a wafer chuck comprising a support surface and configured to receive and secure in place a wafer substrate, wherein the target surface is arranged parallel to the support surface.

Embodiment 40 is the method of any one of embodiments 24 to 39, wherein the depositing of material onto the wafer substrate at normal incidence comprises depositing a bulk layer.

Embodiment 41 is the method of embodiment 40, wherein the bulk layer is deposited onto an inclined c-axis seed layer deposited in the off-axis module.

Embodiment 42 is the method of any one of embodiments 24 to 41 comprising, while depositing material onto the wafer substrate, transferring a second wafer substrate from the central wafer transfer unit to a second off-axis module and depositing material onto the second wafer substrate at an inclined c-axis.

Embodiment 43 is the method of any one of embodiments 24 to 42, wherein the load lock has a pressure in the range of 1·10-4 Torr to 1·10-8 Torr, or from 1·10-6 Torr to 1·10-7 Torr.

Embodiment 44 is the method of any one of embodiments 24 to 43, wherein the pressure in the central wafer transfer unit may be in the range of 1·10-7 Torr to 1·10-8 Torr.

Embodiment 45 is the method of any one of embodiments 24 to 44, wherein the pressure within the deposition modules (e.g., off-axis module and longitudinal module) may be in the range of 5·10-9 Torr to 1·10-2 Torr.

Embodiment 46 is the method of any one of embodiments 24 to 45, wherein the method comprises deposition of a first portion in a first growth step using the off-axis module under deposition conditions comprising a pressure of 5 mTorr or less. In an embodiment, the first growth step is performed at off-normal incidence. Preferably, the deposited layer has a c-axis tilt of about 35 degrees or greater. In an embodiment, the layer may be deposited at a deposition angle of about 35 degrees to about 85 degrees. Preferably, the deposition in the first growth step is under conditions that retard surface mobility of the material being deposited such that crystals in the bulk material layer are substantially parallel to one another and are substantially oriented in a direction of the preselected angle.

Embodiment 47 is the method of any one of embodiments 24 to 46, wherein the method further comprises deposition of a second portion in a second growth step using the longitudinal module, including depositing a bulk material layer at a smaller incidence angle, e.g., at about a normal incidence. In an embodiment, the second portion of the layer deposited in the second growth step orients to the c-axis tilt of the first portion, e.g., about 35 degrees or greater. In an embodiment, the bulk material exhibits a ratio of shear coupling to longitudinal coupling of 1·25 or greater during excitation. In an embodiment, the bulk layer (e.g., the second portion) has an outer surface having a surface roughness (Ra) of 4.5 nm or less.

Embodiment 48 is the method of any one of embodiments 24 to 47, wherein the bulk layer is prepared such that the c-axis orientation of the crystals in the bulk layer is selectable within a range of about 0 degrees to about 90 degrees, such as from about 30 degrees to about 52 degrees, or from about 35 degrees to about 46 degrees. The c-axis orientation distribution is preferably substantially uniform over the area of a large substrate (e.g., having a diameter in a range of at least about 50 mm or greater, about 100 mm or greater, or about 150 mm or greater), thereby enabling multiple chips to be derived from a single substrate and having the same or similar acoustic wave propagation characteristics.

Embodiment 49 is the method of any one of embodiments 24 to 48, wherein the bulk material layer (including the seed layer and the bulk layer) deposited using the system and method of the present disclosure has a thickness of about 1,000 Angstroms to about 30,000 Angstroms. The bulk material layer may be deposited at a deposition angle of about 35 degrees to about 85 degrees. The bulk material may exhibit a ratio of shear coupling to longitudinal coupling of 1·25 or greater during excitation.

Embodiment 50 is a bulk acoustic wave (“BAW”) device comprising a bulk material layer prepared according to the method of any one of embodiments 24 to 49.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. It should be understood that this disclosure is not intended to be unduly limited by the illustrative embodiments and examples set forth herein and that such examples and embodiments are presented by way of example only with the scope of the disclosure intended to be limited only by the claims set forth here.

1. A system for depositing material onto a substrate, the system comprising:
two or more process modules comprising:
an off-axis module constructed to deposit material at an inclined c-axis; and
a longitudinal module constructed to deposit material at normal incidence;
a central wafer transfer unit comprising a load lock, a vacuum chamber, and a robot disposed within the vacuum chamber and constructed to transfer a wafer substrate between the central wafer transfer unit and the two or more process modules; and
a control unit operatively connected to the robot.

2. The system of claim 1, wherein the central housing unit comprises a cooling station constructed to control wafer temperature.

3. The system of claim 1, wherein the two or more process modules comprise a pre-sputter module constructed to prepare wafer substrates for deposition of material.

4. The system of claim 3, wherein the pre-sputter module comprises a plasma sputtering device.

5. The system of claim 3, wherein the pre-sputter module comprises a degassing unit, a wafer heater, or both.

6. The system of claim 1, wherein the central wafer transfer unit is positioned centrally between the two or more process modules.

7. The system of claim 1, wherein each of the two or more process modules comprises an internal environment that is controlled separately from the central wafer transfer unit.

8. The system of claim 1, wherein each of the two or more process modules is separated from the central housing unit by a valve.

9. The system of claim 1, wherein the robot is constructed to transfer the wafer substrate in a horizontal position.

10. The system of claim 1, wherein the off-axis module comprises a wafer chuck constructed to receive the wafer substrate.

11. The system of claim 10, wherein the wafer chuck is constructed to receive the wafer substrate in a horizontal position and to rotate the wafer substrate to a vertical position.

12. The system of claim 11, wherein the wafer chuck is constructed to translate the wafer substrate in the vertical position.

13. The system of claim 1 further comprising a cassette elevator for housing a plurality of wafer substrates accessible by the robot.

14. The system of claim 13, wherein the robot is constructed to retrieve a wafer substrate from the cassette elevator and to transfer the retrieved wafer substrate to one of the process modules.

15. The system of claim 1, wherein the off-axis module comprises a chamber, a vacuum pump constructed to create a vacuum in the chamber, and a linear sputtering apparatus housed within the chamber, wherein the chamber is separated from the central housing unit by a gate valve.

16. The system of claim 1, wherein the off-axis module comprises:
a linear sputtering apparatus comprising a target surface configured to eject metal atoms;
a wafer chuck comprising a support surface and configured to receive and secure in place a wafer substrate; and
a collimator comprising a plurality of guide members defining a plurality of collimator apertures arranged between the linear sputtering apparatus and the wafer chuck, the collimator being linearly translatable in a direction substantially parallel to the target surface,
wherein the target surface is arranged non-parallel to the support surface.

17. The system of claim 16, wherein the linear sputtering apparatus comprises a linear magnetron with a sputtering cathode operatively coupled to the target surface to promote ejection of metal atoms from the target surface.

18. The system of claim 17, wherein the support surface is disposed along a vertical plane that is non-parallel to the target surface.

19. The system of claim 18, wherein the target surface has a longitudinal axis that is oriented along a horizontal line.

20. The system of claim 19, wherein the support surface is configured to ratchet up and down along its vertical plane.

21. The system of claim 1 further comprising a second off-axis module.

22. The system of claim 1, wherein the longitudinal module comprises a chamber, a vacuum pump constructed to create a vacuum in the chamber, and a circular sputtering apparatus housed within the chamber, wherein the chamber is separated from the central housing unit by a gate valve.

23. The system of claim 1, wherein the longitudinal module comprises:
a circular sputtering apparatus comprising a target surface configured to eject metal atoms; and
a wafer chuck comprising a support surface and configured to receive and secure in place a wafer substrate,
wherein the target surface is arranged parallel to the support surface.

24-42. (canceled)
